(19) United States
(12) Patent Application Publication
(10) Pub. No.: US 2025/0006469 A1
(43) Pub. Date: Jan. 2, 2025

(54) MANIFOLD FOR SUPPLYING COOLANT TO COMPONENTS OF SUBSTRATE PROCESSING SYSTEMS

(71) Applicant: LAM RESEARCH CORPORATION, Fremont, CA (US)

(72) Inventor: Miguel Benjamin VASQUEZ, Portland, OR (US)

(21) Appl. No.: 18/712,439

(22) PCT Filed: Dec. 6, 2022
(86) PCT No.: PCT/US2022/051976

§ 371 Date: May 22, 2024

Related U.S. Application Data
(60) Provisional application No. 63/288,505, filed on Dec. 10, 2021.

(51) Int. Cl. H01J 37/32; H01L 21/677; H01L 21/687

(52) U.S. Cl. CPC H01J 37/32522; H01J 37/32513; H01L 21/67742; H01J 2237/332; H01J 2237/334; H01L 21/68742

(57) ABSTRACT

A device for supplying a coolant to a substrate processing chamber includes a block including a plurality of surfaces and a plurality of passages defined within the block. The device includes an input port located on a first surface to receive the coolant. The device includes a first set of ports located on a second surface to supply the coolant to a first component of the substrate processing chamber. The first set of ports is in fluid communication with the input port via a first passage. The device includes a second set of ports located on a third surface to receive the coolant from the first component. The device includes an output port located on a fourth surface to supply the coolant to a second component of the substrate processing chamber. The output port is in fluid communication with the second set of ports via a second passage.

### CROSS-REFERENCE TO RELATED APPLICATIONS

This application is a U.S. National Phase application under 35 U.S.C. 371 of International Application No. PCT/US2022/051976, filed on Dec. 6, 2022, which claims the benefit of U.S. Provisional Application No. 63/288,505, filed on Dec. 10, 2021. The entire disclosures of the above applications are incorporated herein by reference.

### FIELD

The present disclosure relates generally to substrate processing systems and more particularly to a manifold for supplying coolant to components of the substrate processing systems.

### BACKGROUND

The background description provided here is for the purpose of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

Substrate processing systems (also called tools) comprise processing chambers. Some processing chambers comprise multiple stations. Each station comprises a pedestal and a showerhead. A substrate such as a semiconductor wafer is arranged on the pedestal during processing. One or more process gases are supplied from the showerhead during processing. Plasma is struck between the showerhead and the pedestal to deposit material on or to remove (etch) material from the substrate. A robot is arranged on a spindle to transfer the substrate from one station to another.

### SUMMARY

A device for supplying a coolant to a substrate processing chamber comprises a block comprising a plurality of surfaces and a plurality of passages defined within the block. The device comprises an input port located on a first surface of the plurality of surfaces to receive the coolant. The device comprises a first set of ports located on a second surface of the plurality of surfaces to supply the coolant to a first component of the substrate processing chamber. The first set of ports is in fluid communication with the input port via a first passage of the plurality of passages. The device comprises a second set of ports located on a third surface of the plurality of surfaces to receive the coolant from the first component. The device comprises an output port located on a fourth surface of the plurality of surfaces to supply the coolant to a second component of the substrate processing chamber. The output port is in fluid communication with the second set of ports via a second passage of the plurality of passages.

In additional features, the first and fourth surfaces are the same.

In additional features, the second and third surfaces are the same.

In additional features, each of the first and second sets of ports includes a plurality of ports.

In additional features, each of the first and second sets of ports includes a single port.

In additional features, the first and second passages are disjoint.

In additional features, the device further comprises a first set of fittings extending from the first set of ports to connect the first set of ports to a first set of conduits, respectively. The first set of conduits supply the coolant to the first component. The device further comprises a second set of fittings extending from the second set of ports to connect the second set of ports to a second set of conduits, respectively. The second set of conduits receives the coolant from the first component.

In additional features, the first and second sets of fittings and the device are monolithic.

In additional features, the device further comprises a first set of boots arranged coaxially around the first set of fittings and around portions of the first set of conduits extending from the first set of fittings. The device further comprises a second set of boots arranged coaxially around the second set of fittings and around portions of the second set of conduits extending from the second set of fittings.

In additional features, the first and second sets of boots are made of a flexible leakproof material.

In additional features, the first and second sets of boots are made of rubber.

In additional features, portions of the first and second sets of boots surround the first and second sets of fittings. The first and second sets of fittings are shaped differently than the portions of the first and second sets of boots to leave a gap between the first and second sets of fittings and the portions of the first and second sets of boots.

In additional features, the first and second sets of boots comprise first portions that surround the first and second sets of fittings, second portions that extend from the first portions and that are bellowed, and third portions that extend from the second portions and that surround portions of the first and second sets of conduits.

In additional features, the first and second sets of fittings are shaped differently than the first portions of the first and second sets of boots to leave a gap between the first and second sets of fittings and the first portions of the first and second sets of boots.

In additional features, in response the coolant leaking from at least one of the first and second sets of fittings, the leaked coolant accumulates in the second portion of at least one of the boots and flows through the gap.

In additional features, in response the coolant leaking from at least one of the portions of the first and second sets of conduits, the leaked coolant accumulates in the second portion of at least one of the boots and flows through the gap.

In additional features, a system comprises the device and a radio frequency power supply to supply radio frequency power to the substrate processing chamber, The radio frequency power supply is located adjacent the device. In response the coolant leaking from at least one of the first and second sets of fittings, at least one of the boots prevent the leaking coolant from the at least one of the first and second sets of fittings from flowing to the radio frequency power supply.

In additional features, a system comprises the device and a radio frequency power supply to supply radio frequency power to the substrate processing chamber. The radio frequency power supply is located adjacent the device. In response the coolant leaking from at least one of the portions of the first and second sets of conduits, at least one of the boots prevent the leaking coolant from the at least one of the portions of the first and second sets of conduits from flowing to the radio frequency power supply.

In additional features, a system comprises the device and the substrate processing chamber. The substrate processing chamber comprises a plurality of stations and a spindle with a robot to transfer the substrate between the stations. The stations comprises respective pedestals to support a substrate and respective pedestal lift assemblies to move the pedestals. The spindle is the first component. The second component comprises at least one of the pedestal lift assemblies.

In additional features, the first and second sets of ports are connected to the spindle via respective conduits. The output port is connected to the at least one of the pedestal lift assemblies via one or more conduits.

In additional features, the first and second sets of ports are connected to the spindle via respective conduits. The output port is connected to two of the pedestal lift assemblies via a conduit that is bifurcated to the two of the pedestal lift assemblies.

In additional features, the system further comprises a coolant source to supply the coolant to the input port via a first conduit and to receive the coolant from one of the pedestal lift assemblies via a second conduit.

In additional features, the system further comprises a radio frequency power supply to supply radio frequency power to the stations. The radio frequency power supply is located adjacent the device and at least partially under the at least one of the pedestal lift assemblies. The radio frequency power supply comprises an enclosure, a cover attached to the enclosure, and a plurality of sealing assemblies to seal gaps between the cover and the enclosure.

In additional features, the sealing assemblies are shaped to avoid attachments of the radio frequency power supply mounted to at least one of the enclosure and the cover of the radio frequency power supply.

In additional features, the sealing assemblies are configured to fold around edges and corners of the enclosure and the cover.

In additional features, the output port is connected to the at least one of the pedestal lift assemblies via one or more conduits. In response to the coolant leaking from the one or more conduits, the sealing assemblies prevent the leaking coolant from the one or more conduits from precipitating on the radio frequency power supply.

In additional features, the system further comprises a radio frequency power supply to supply radio frequency power to the stations. The radio frequency power supply is located adjacent the device. The radio frequency power supply comprises a first power supply comprising a first enclosure and a first cover attached to the first enclosure. The radio frequency power supply comprises a second power supply comprising a second enclosure and a second cover attached to the second enclosure. The second power supply is of a smaller footprint than the first power supply and being stacked on the first power supply. The radio frequency power supply comprises a plurality of sealing assemblies to seal gaps between the first cover and the first enclosure and between the second cover and the second enclosure. The sealing assemblies are shaped to avoid attachments of the first and second power supplies. The attachments are mounted to at least one of the first enclosure and the first cover of the first power supply and to at least one of the second enclosure and the second cover of the second power supply.

In additional features, the output port is connected to the at least one of the pedestal lift assemblies via one or more conduits. In response to the coolant leaking from the one or more conduits, the sealing assemblies prevent the leaking coolant from the one or more conduits from precipitating on at least one of the first and second power supplies.

In additional features, the sealing assemblies are configured to fold around edges and corners of the first enclosure and the first cover and around edges and corners of the second enclosure and the second cover.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a processing chamber comprising multiple stations with pedestals for processing substrates and a spindle with a robot for transferring the substrates between the stations;

FIG. 2 shows a coolant supply system comprising a manifold and shows connections of the manifold to the pedestals and the spindle of the processing chamber of FIG. 1;

FIG. 3 shows a perspective view of the manifold of FIG. 2;

FIGS. 4A-4D show various views of the manifold of FIG. 3;

FIGS. 5A and 5B show rubber boots used with the manifold of FIG. 3;

FIGS. 6A and 6B show a general layout of the coolant manifold and high frequency (HF) and low frequency (LF) power supplies in the processing chamber of FIG. 1;

FIGS. 7A-7D show examples of sealing assemblies used for sealing a top cover to an enclosure of the HF power supply; and

FIGS. 8A-8C show examples of sealing assemblies used for sealing a top cover to an enclosure of the LF power supply.

In the drawings, reference numbers may be reused to identify similar and/or identical elements.

### DETAILED DESCRIPTION

In some tools, the pedestals in the stations can be moved up and down relative to the showerhead using respective pedestal lift assemblies. The spindle used to transfer substrates from one station to another and the pedestal lift assemblies are water-cooled. Water is supplied to the spindle and the pedestal lift assemblies through various conduits. The conduits are routed through compact spaces under and around the spindle and the pedestal lift assemblies. The routing of the conduits typically involves joining portions of the conduits at multiple locations. The joints are sources of possible leaks. A radio frequency (RF) power supply or other high voltage equipment, which is used to strike plasma in the stations, is generally located adjacent to the spindle and under one or more pedestal lift assemblies. Water leaking from the joints poses a hazard for the RF power supply.

The present disclosure provides a manifold to supply a coolant such as water to the spindle and the pedestal lift assemblies. The manifold eliminates many of the joints in the conduits and simplifies the routing of the conduits to supply water to the spindle and the pedestal lift assemblies. In addition, rubber boots are used to cover the connections of the conduits to fittings provided on the manifold. The rubber boots are bellowed and cover portions of the conduits above the fittings. The fittings are generally cylindrical with a cutout along the side (height) of the fittings. If water leaks at or near the fittings, the bellowed rubber boots prevent the leaking water from spraying onto the RF power supply located adjacent to the manifold. In addition, water collected in the rubber boots flows out of the rubber boots through the cutouts to the bottom of the processing chamber without spilling or spraying on the RF power supply. One or more sensors at the bottom of the processing chamber detect the leak so that the leak can be fixed.

Further, water can leak from the connections to one or more pedestal lift assemblies located above the RF power supply. The leaking water can drop on top of the RF power supply located below the one or more pedestal lift assemblies. The RF power supply includes a high frequency (HF) power supply that is stacked on top of a low frequency (LF) power supply. The HF and LF power supplies are enclosed in respective enclosures with respective top covers. The fittings between the top covers and the enclosures are typically not leakproof. Specifically, gaps exist between the top covers and the enclosures. Water can flow through the gaps into the HF and LF power supplies. The present disclosure provides sealing assemblies that are specifically shaped to cover (seal) the gaps and to prevent water from leaking into the HF and LF power supplies. These and other features of the present disclosure are described below in detail.

Throughout the present disclosure, the spindle and the pedestals are used only as examples of components of the substrate processing system to which a coolant is supplied. Generally, the coolant or coolants are typically supplied to various other components of the substrate processing system. The teachings of the present disclosure are also applicable to supplying the coolant or coolants to these other components.

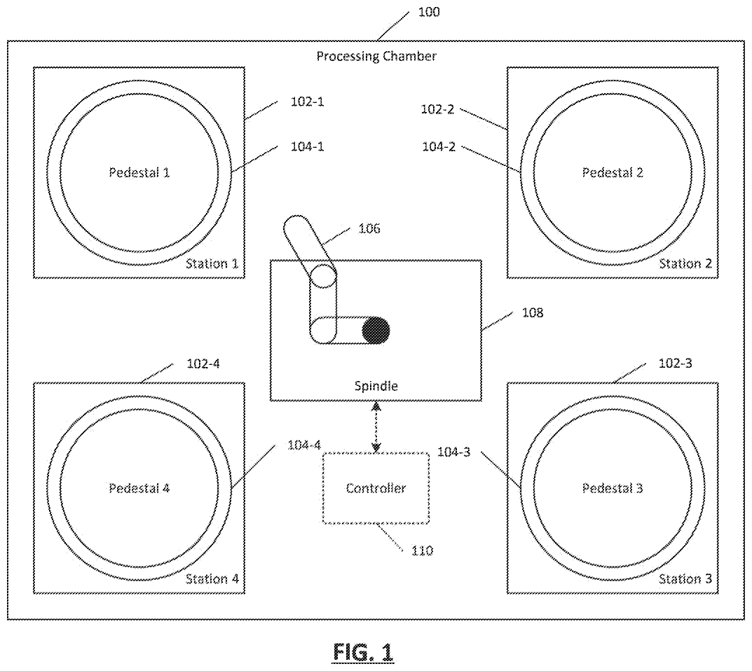

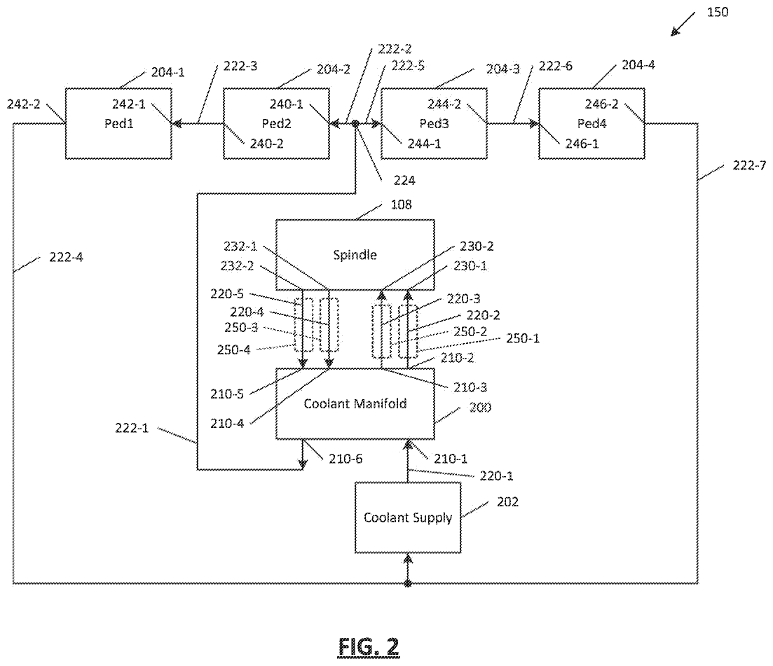

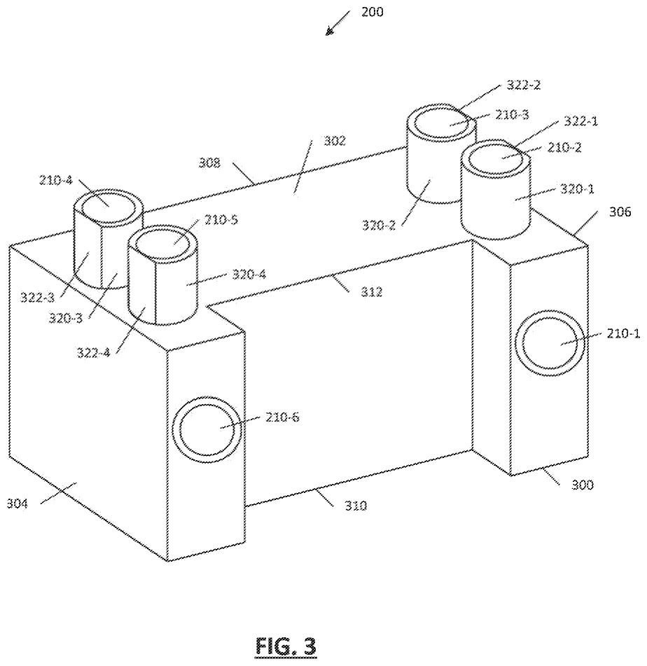

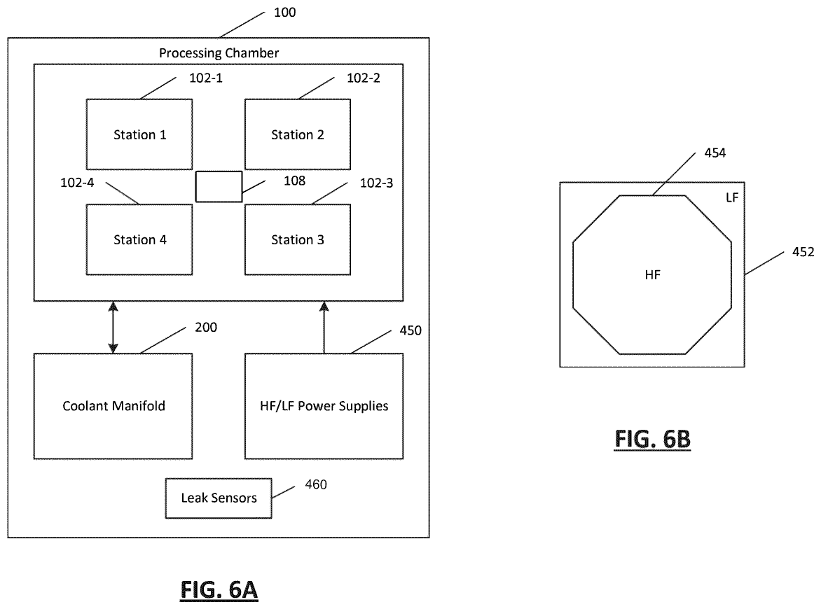

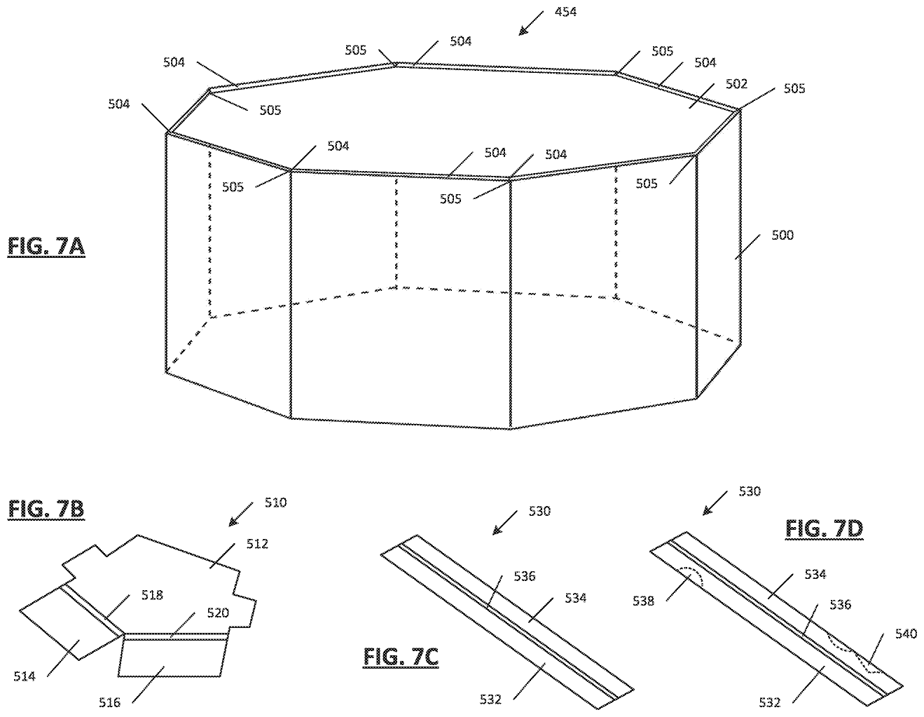

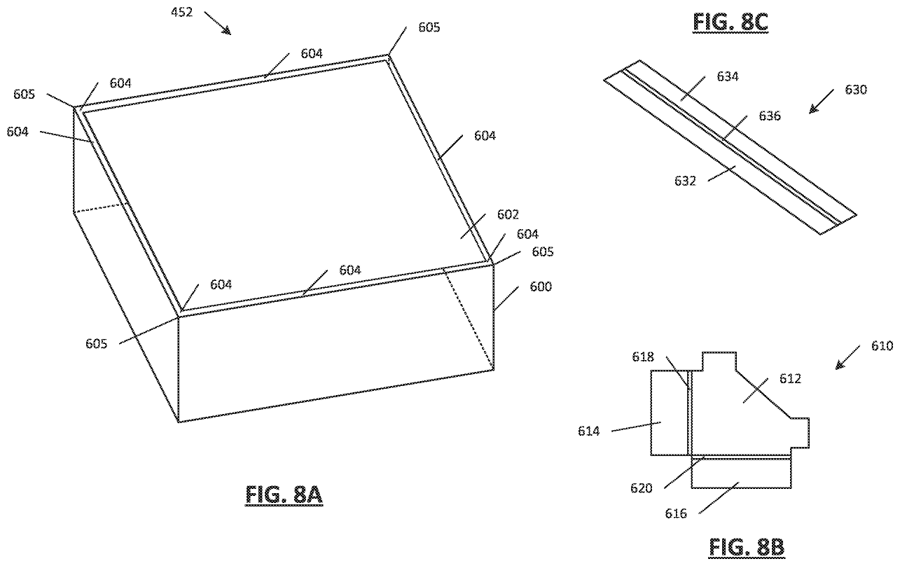

The present disclosure is organized as follows. FIG. 1 shows a general layout of a processing chamber. FIG. 2 schematically shows the manifold and connections from the manifold to the spindle and the pedestal lift assemblies of the processing chamber. FIGS. 3-5B show the manifold and the rubber boots in detail. FIGS. 6A and 6B show a general layout of the manifold and the HF and LF power supplies. FIGS. 7A-8C show the sealing assemblies for the top covers of the HF and LF power supplies.

FIG. 1 shows a plan view of a processing chamber 100 comprising a plurality of stations 102-1, 102-2, 102-3, and 102-4 (collectively the stations 102). While four stations 102 are shown for example only, the processing chamber 100 may comprise any number of stations. The stations 102 respectively include pedestals 104-1, 104-2, 104-3, and 104-4 (collectively the pedestals 104). The pedestals 104 are moved by respective pedestal lift assemblies (shown in FIG. 2). A robot 106 is arranged on a spindle 108 to transfer substrates between the stations 102. A controller 110, which is typically located outside the processing chamber 100 (and hence shown dotted), controls the robot 106 and the pedestal lift assemblies.

FIG. 2 shows a coolant supply system 150 comprising a coolant manifold 200 according to the present disclosure. The coolant supply system 150 supplies a coolant such as water from a coolant supply 202 to the spindle 108 and the pedestals 204 via the coolant manifold 200. The coolant manifold 200 receives the coolant from the coolant supply 202 and supplies the coolant to the spindle 108. The coolant supplied from the coolant manifold 200 to the spindle 108 is returned from the spindle 108 to the coolant manifold 200. The coolant manifold 200 supplies the coolant returned from the spindle 108 to the pedestal lift assemblies shown as Ped1 204-1, Ped2 204-2, Ped3 204-3, and Ped4 204-4 (collectively the pedestal lift assemblies 204). The pedestal lift assemblies 204 are used to move the respective pedestals 104 in the processing chamber 100 (shown in FIG. 1) in upward and downward directions. For convenience, the pedestal lift assemblies 204 are hereinafter simply called the pedestals 204.

The coolant manifold 200 is shown and described in detail with reference to FIGS. 3-5B. Briefly, the coolant manifold 200 receives the coolant from the coolant supply 202. The coolant manifold 200 first supplies the coolant received from the coolant supply 202 to the spindle 108. The coolant manifold 200 receives the coolant returned from the spindle 108. The coolant manifold 200 then supplies the coolant returned from the spindle 108 to the pedestals 204. The coolant from the pedestals 204 is returned to the coolant supply 202.

Specifically, the coolant manifold 200 includes six ports 210-1, 210-2, 210-3, 210-4, 210-5, and 210-6 (collectively the ports 210). The first port (also called a main inlet or a main input port) 210-1 of the coolant manifold 200 is connected to the coolant supply 202 by a conduit 220-1. The first port 210-1 receives the coolant from the coolant supply 202 via the conduit 220-1. The coolant received from the coolant supply 202 through the conduit 220-1 flows into the coolant manifold 200 via the first port 210-1. The coolant flows out of the coolant manifold 200 via the second and third ports 210-2, 210-3 of the coolant manifold 200. The second and third ports 210-2, 210-3 are also called a pair of outlets (or output ports) of the coolant manifold 200. The second and third ports 210-2, 210-3 are connected to the spindle 108.

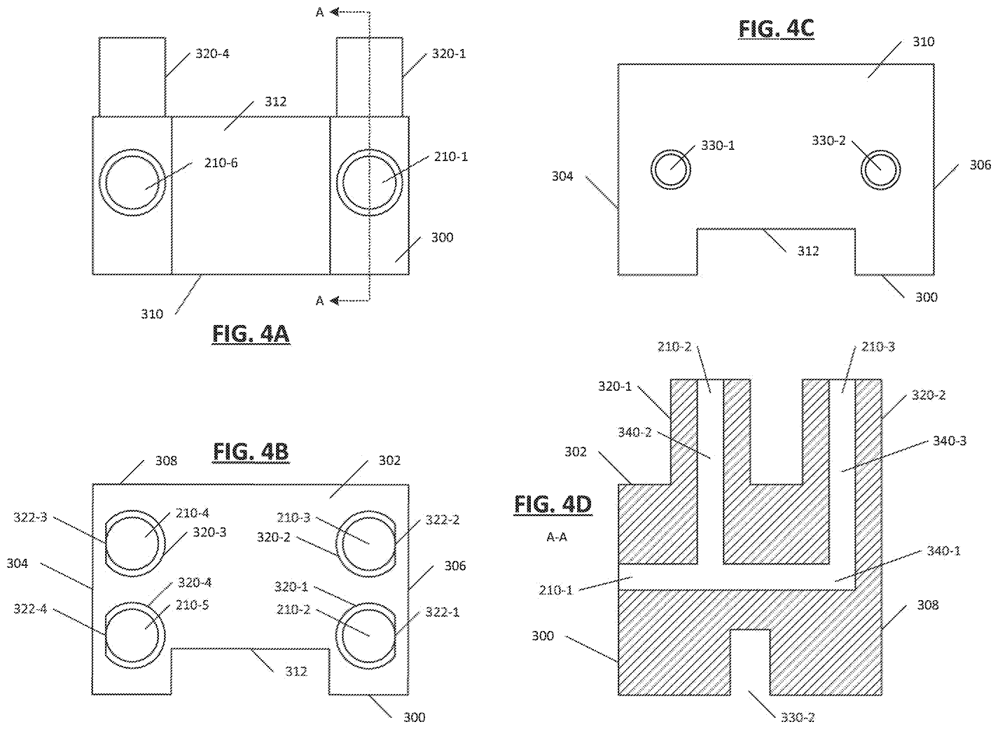

The spindle 108 includes two inlets 230-1, 230-2 and two outlets 232-1, 232-2. The second and third ports 210-2, 210-3 of the coolant manifold 200 are connected to the inlets 230-1, 230-2 of the spindle 108 by respective conduits 220-2, 220-3. The coolant manifold 200 comprises internal passages (shown in FIG. 4D) that connect the first port 210-1 of the coolant manifold 200 to the second and third ports (i.e., the pair of outlets) 210-2, 210-3 of the coolant manifold 200. The coolant flows from the first port 210-1 of the coolant manifold 200 to the second and third ports 210-2, 210-3 of the coolant manifold 200 via the internal passages of the coolant manifold 200.

The fourth and fifth ports 210-4, 210-5 of the coolant manifold 200 are connected to the outlets 232-1, 232-2 of the spindle 108 by respective conduits 220-4, 220-5. The coolant that flows into the spindle 108 through the inlets 230-1, 230-2 of the spindle 108 flows out of the spindle 108 through the outlets 232-1, 232-2 of the spindle 108. The coolant from the spindle 108 is returned to the coolant manifold 200 via the outlets 232-1, 232-2 of the spindle 108, the respective conduits 220-4, 220-5, and the fourth and fifth ports 210-4, 210-5 of the coolant manifold 200. The fourth and fifth ports 210-4, 210-5 are also called a pair of inlets of the coolant manifold 200.

The fourth and fifth ports (i.e., the pair of inlets or input ports) 210-4, 210-5 of the coolant manifold 200 are connected to the sixth port 210-6 of the coolant manifold 200 by the internal passages of the coolant manifold 200 (shown in FIG. 4D). The sixth port 210-6 of the coolant manifold 200 is also called a main outlet or a main output port of the coolant manifold 200. The coolant returned from the spindle 108 to the coolant manifold 200 flows out of the coolant manifold 200 via the sixth port 210-6 of the coolant manifold 200.

The sixth port 210-6 of the coolant manifold 200 is connected to the pedestals 204 via multiple conduits. For example, a first conduit 222-1 is connected to the sixth port 210-6 of the coolant manifold 200. The flow of the coolant from the first conduit 222-1 is bifurcated to the pedestals 204 via two branches. Each pedestal 204 includes an inlet and an outlet. A first set of two pedestals 204 (e.g., the first and second pedestals 204-1, 204-2) is connected to a first branch of the first conduit 222-1 as described below. A second set of two pedestals 204 (e.g., the third and fourth pedestals 204-3, 204-4) is connected to a second branch of the first conduit 222-1 as described below.

For example, in a first branch, a second conduit 222-2 branches off a distal end of the first conduit 222-1 (e.g., via a T-joint 224). The second conduit 222-2 is connected to an inlet 240-1 of the second pedestal 204-2. A third conduit 222-3 is connected to an outlet 240-2 of the second pedestal 204-2 and is connected to an inlet 242-1 of the first pedestal 204-1. A fourth conduit 222-4 is connected to an outlet 242-2 of the first pedestal 204-1 and is connected to the coolant supply 202.

A first portion of the coolant from the first conduit 222-1 flows through the T-joint 224 into the second conduit 222-2. The first portion of the coolant flows through the second conduit 222-2 into the inlet 240-1 of the second pedestal 204-2 and flows out of the outlet 240-2 of the second pedestal 204-2. The first portion of the coolant flows out of the outlet 240-2 of the second pedestal 204-2 into the third conduit 222-3. The first portion of the coolant flows through the third conduit 222-3 into the inlet 242-1 of the first pedestal 204-1. The first portion of the coolant flows out of the outlet 242-2 of the first pedestal 204-1. The first portion of the coolant flows through the outlet 242-2 of the first pedestal 204-1 into the fourth conduit 222-4. The first portion of the coolant is returned to the coolant supply 202 via the fourth conduit 222-4.

In a second branch, a fifth conduit 222-5 branches off the distal end of the first conduit 222-1 (e.g., via the T-joint 224). The fifth conduit 222-5 is connected to an inlet 244-1 of the third pedestal 204-3. A sixth conduit 222-6 is connected to an outlet 244-2 of the third pedestal 204-3 and is connected to an inlet 246-1 of the fourth pedestal 204-4. A seventh conduit 222-7 is connected to an outlet 246-2 of the fourth pedestal 204-4 and is connected to the coolant supply 202.

A second portion of the coolant from the first conduit 222-1 flows through the T-joint 224 into the fifth conduit 222-5. The second portion of the coolant flows through the fifth conduit 222-5 into the inlet 244-1 of the third pedestal 204-3 and flows out of the outlet 244-2 of the third pedestal 204-3. The second portion of the coolant flows out of the outlet 244-2 of the third pedestal 204-3 into the sixth conduit 222-6. The second portion of the coolant flows through the sixth conduit 222-6 into the inlet 246-1 of the fourth pedestal 204-4. The second portion of the coolant flows out of the outlet 246-2 of the fourth pedestal 204-4. The second portion of the coolant flows through the outlet 246-2 of the fourth pedestal 204-4 into the seventh conduit 222-7. The second portion of the coolant is returned to the coolant supply 202 via the seventh conduit 222-7.

The coolant from the first conduit 222-1 can be supplied to the spindle 108 and the pedestals 204 using other arrangements. In any arrangement, the coolant from the coolant supply 202 is supplied to the coolant manifold 200. The coolant manifold 200 first supplies the coolant to the spindle 108. The coolant is returned from the spindle 108 to the coolant manifold 200. The coolant returned from the spindle 108 is then supplied to the pedestals 204. The coolant from the pedestals 204 is returned to the coolant supply 202.

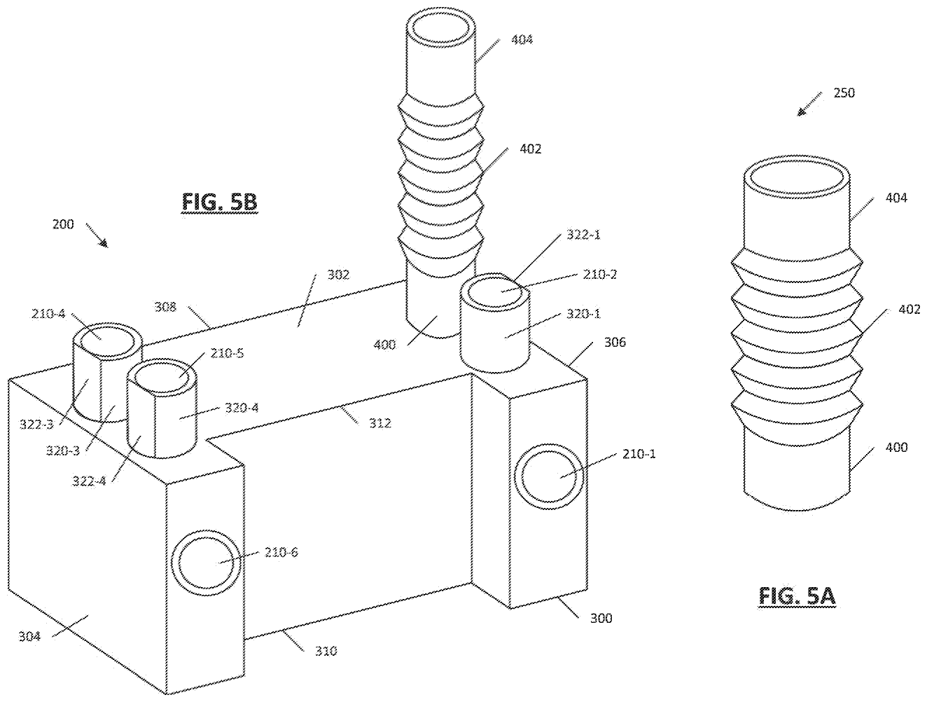

On portions of each of the conduits 220-2, 220-3, 220-4, and 220-5, rubber boots 250-1, 250-2, 250-3, and 250-4 (collectively the rubber boots 250) are arranged. The rubber boots 250 are shown and described in detail with reference to FIGS. 5A and 5B. Briefly, a first pair of the rubber boots 250-1, 250-2 cover the second and third ports (i.e., the pair of outlets) 210-2, 210-3 of the coolant manifold 200, respectively. Additionally, the first pair of the rubber boots 250-1, 250-2 also cover portions of the conduits 220-2, 220-3 connected to the second and third ports (i.e., the pair of outlets) 210-2, 210-3 of the coolant manifold 200, respectively. A second pair of the rubber boots 250-3, 250-4 cover the fourth and fifth ports (i.e., the pair of inlets) 210-4, 210-5 of the coolant manifold 200, respectively. The second pair of the rubber boots 250-3, 250-4 also cover portions of the conduits 220-4, 220-5 connected to the fourth and fifth ports (i.e., the pair of inlets) 210-4, 210-5 of the coolant manifold 200, respectively. The rubber boots 250 control any coolant leaking from the conduits 220-2, 220-3, 220-4, and 220-5 and from the second, third, fourth, and fifth ports 210-2, 210-3, 210-4, 210-5 of the coolant manifold 200. The rubber boots 250 prevent any of the leaking coolant from spraying or spilling over neighboring RF power supply located adjacent to the coolant manifold 200 as shown and described in detail with reference to FIGS. 5A-6B.

Additionally, while not shown in the coolant supply system 150, various valves may be used in conjunction with the conduits 220 and 222 to control the flow of the coolant from the coolant supply 202 to the coolant manifold 200, the spindle 108, and the pedestals 204. The controller 110 shown in FIG. 1 can control the flow of the coolant from the coolant supply 202 to the coolant manifold 200, the spindle 108, and the pedestals 204 by controlling the coolant supply 202 and the valves of the coolant supply system 150.

In some examples, the coolant manifold 200 may be configured with different number and arrangement of ports. For example, the ports may be arranged on different surfaces of the coolant manifold 200 than as shown. In some examples, the ports of the coolant manifold 200 and corresponding conduits 220, 222 may be arranged such that the coolant may be supplied first to the pedestals 204. The coolant returned from the pedestals 204 may then be supplied to the spindle 108, and the coolant from the spindle 108 is then returned to the coolant supply 202. In some examples, the ports of the coolant manifold 200 and corresponding conduits 220, 222 may be arranged such that the coolant may be supplied to the spindle 108 and the pedestals 204 independently of each other (i.e., without supplying coolant received from one device to another device). Further, the coolant can be supplied to the spindle 108 and received from the spindle 108 using respective ports (i.e., using a single pair of ports instead of two pairs of ports). Furthermore, the coolant can be supplied to the pedestals 204 using respective ports. In any of these arrangements, the rubber boots 250 can be used on the input and output ports of the coolant manifold 200 and on portions of conduits connected to the input and output ports to prevent any leaking coolant from spraying or spilling over neighboring RF power supply located adjacent to the coolant manifold 200.

FIG. 3 shows a perspective view of an example of the coolant manifold 200. For example, the coolant manifold 200 may be a rectangular block although blocks having other shapes may be used. For example, the coolant manifold 200 may be made of any type of plastic material although other materials such as metals may also be used. The shape of the coolant manifold 200 can depend on factors such as the mounting location of the coolant manifold 200 in the processing chamber 100, other components of the processing chamber 100 surrounding the coolant manifold 200, the number of stations (i.e., the number of pedestals 204) in the processing chamber 100, and so on.

In the example shown, the coolant manifold 200 is generally rectangular and has six surfaces: a front surface 300; a top surface 302; two side surfaces 304, 306, a back surface 308, and a bottom surface 310. The surfaces 306, 308, 310 are not visible in the view shown. The front surface 300 includes a cutout 312 that is generally C-shaped. The cutout 312 extends from the top surface 302 to the bottom surface 310. The cutout 312 allows routing of other components such as cables and so on around the coolant manifold 200.

The first port 210-1 of the coolant manifold 200 is located on the front surface 300 of the coolant manifold 200. The first port 210-1 is proximate to the intersection of the front surface 300 and the side surface 306 (called a first side surface) of the coolant manifold 200. The sixth port 210-6 of the coolant manifold 200 is also located on the front surface 300 of the coolant manifold 200. The sixth port 210-6 is proximate to the intersection of the front surface 300 and the side surface 304 (called a second side surface) of the coolant manifold 200. In the example shown, the first port 210-1 and the sixth port 210-6 are arranged symmetrically on the first surface 300. However, the first port 210-1 and the sixth port 210-6 can be arranged on the first surface 300 in other ways. For example, one of the first port 210-1 and the sixth port 210-6 may be proximate to the top surface 302 while the other of the first port 210-1 and the sixth port 210-6 may be proximate to the bottom surface 310.

The second, third, fourth, and fifth ports 210-2, 210-3, 210-4, 210-5 are located on the top surface 302 of the coolant manifold 200. The second and third ports 210-2, 210-3 are proximate to the intersection of the top surface 302 and the first side surface 306 of the coolant manifold 200. The fourth and fifth ports 210-4, 210-5 of the coolant manifold 200 are proximate to the intersection of the top surface 302 and the second side surface 304 of the coolant manifold 200. In the example shown, the second, third, fourth, and fifth ports 210-2, 210-3, 210-4, 210-5 are arranged symmetrically on the top surface 302. However, the second, third, fourth, and fifth ports 210-2, 210-3, 210-4, 210-5 can be arranged on the top surface 302 in other ways. For example, one of the second and third ports 210-2, 210-3 may be closer to the first side surface 306 while the other of the second and third ports 210-2, 210-3 may be farther from the first side surface 306. Similarly, one of the fourth and fifth ports 210-4, 210-5 may be closer to the second side surface 304 while the other of the fourth and fifth ports 210-4, 210-5 may be farther from the second side surface 304.

The ports 210 of the coolant manifold 200 include fittings for attaching the conduits to the ports 210. For example, the second, third, fourth, and fifth ports 210-2, 210-3, 210-4, 210-5 respectively include fittings 320-1, 320-2, 320-3, 320-4 (collectively the fittings 320). The fittings 320-1, 320-2, 320-3, 320-4 extend from the second, third, fourth, and fifth ports 210-2, 210-3, 210-4, 210-5, respectively. The fittings 320 are not separate pieces that are attached to the coolant manifold 200. Rather, the fittings 320 are machined in the same continuous piece as the coolant manifold 200. Accordingly, the fittings 320 are integral to the coolant manifold 200, and the fittings 320 and the manifold 200 are unitary and monolithic. The conduits 220-2, 220-3, 220-4, 220-5 (shown in FIG. 2) are respectively fastened to the fittings 320-1, 320-2, 320-3, 320-4. Although not shown, the first and sixth ports 210-1, 210-6 may include similar or other suitable fittings to which the conduits 220-1 and 222-1 (shown in FIG. 2) are respectively fastened.

The fittings 320 are generally cylindrical. Each of the fittings 320 includes a cutout along the length (height) of the fittings 320. For example, the fittings 320-1, 320-2, 320-3, 320-4 respectively include cutouts 322-1, 322-2, 322-3, 322-4 (collectively the cutouts 322). The cutouts 322 are formed by shaving a portion off the fittings 320 along the length (height) of the fittings 320. Due to cutouts 322, the fittings 320 are approximately D-shaped. As explained below in detail with reference to FIGS. 5A and 5B, the rubber boots 250 are mounted on the fittings 320. The rubber boots 250 cover the fittings 320. The cutouts 322 allow any coolant that leaks and accumulates in the rubber boots 250 to exit from the bottom of the rubber boots 250.

FIGS. 4A-4D show various views of the coolant manifold 200. FIG. 4A shows a front view of the coolant manifold 200. FIG. 4B shows a top view of the coolant manifold 200. Elements of the coolant manifold 200 that are visible in the front and top views are already described above with reference to FIG. 3 and are therefore not described again for brevity.

FIG. 4C shows a bottom view of the coolant manifold 200. The bottom surface 310 of the coolant manifold 200 includes a plurality of mounting holes 330-1, 330-2 (collectively the mounting holes 330). For example, the mounting holes 330 may be threaded or unthreaded to accept suitable fasteners (not shown). The coolant manifold 200 can be mounted or fastened to a mounting bracket using the mounting holes 330 and suitable fasteners. While two mounting holes 330 are shown for example only, the bottom surface 310 may include any number of mounting holes 330 (e.g., one, three, four, etc.). Further, while the mounting holes 330 are shown on the bottom surface 310 of the coolant manifold 200, the mounting holes 330 can be located on any of the surfaces of the coolant manifold 200 depending on the mounting location of the coolant manifold 200.

FIG. 4D shows a cross-sectional view of the coolant manifold 200 taken along the line A-A shown in FIG. 4A. The coolant manifold 200 comprises a plurality of passages. For example, a first passage 340-1 extends from the first port 210-1 on the front surface 300 of the coolant manifold 200 towards the back surface 308 of the coolant manifold 200. The first passage 340-1 extends parallel to the top and bottom surfaces 302, 310 of the coolant manifold 200. A second passage 340-2 extends from a center portion of the first passage 340-1 to the second port 210-2. A third passage 340-3 extends from a distal end of the first passage 340-1 to the third port 210-3. The second and third passages 340-2, 340-3 extend perpendicularly to the first passage 340-1. The first, second, and third passages 340-1, 340-2, 340-3 are collectively called a first set of internal passages 340 of the coolant manifold 200.

The first set of internal passages 340 fluidly connect the first port 210-1 to the second and third ports 210-2, 210-3. The first set of internal passages 340 are in fluid communication with each other and with the first, second, and third ports 210-1, 210-2, 210-3. A similar second set of internal passages fluidly connects the fourth, fifth, and sixth ports 210-4, 210-5, 210-6 of the coolant manifold 200. The first and second sets of the internal passages in the coolant manifold 200 are separate (disjoint) from each other and are not connected to each other.

FIGS. 5A and 5B show the rubber boots 250 in detail. FIG. 5A shows an example of one of the rubber boots 250. FIG. 5B shows an example of one of the rubber boots 250 mounted on one of the fittings 320 (e.g., the fitting 320-2). All of the rubber boots 250 have the same structure and are mounted on the respective fittings 320 as described below. While the boots 250 are called rubber boots throughout the present disclosure, it is understood that the boots 250 can be made of any flexible and leakproof material instead.

In FIG. 5A, the rubber boot 250 comprises a first cylindrical portion 400, a bellowed portion 402, and a second cylindrical portion 404. The bellowed portion 402 extends from the first cylindrical portion 400. The second cylindrical portion 404 extends from the bellowed portion 402. The first cylindrical portion 400 mounts on one of the fittings 320 (e.g., the fitting 320-2) as shown in FIG. 5B. For example, an inner diameter (ID) of the first cylindrical portion 400 matches an outer diameter (OD) of the fittings 320. The bellowed portion 402 and the second cylindrical portion 404 cover (surround) a portion of the conduit that connects to the fitting 320. For example, in the example shown in FIG. 5B, the conduit 220-2 (shown in FIG. 2) is attached to the fitting 320-2 (shown in FIG. 3). The rubber boot 250 extends from the fitting 320-2 and surrounds (i.e., covers or encloses) a portion or length of the conduit 220-2. The fitting 320-2, the rubber boot 250, and the conduit 220-2 are coaxial.

If the coolant leaks from the fitting 320-2 and/or from the conduit 220-2, the leaked coolant accumulates in the bellowed portion 402 of the rubber boot 250. The leaked coolant does not splash on components surrounding the coolant manifold 200 (e.g., an RF power supply located adjacent to the coolant manifold 200 as shown in FIG. 6A). A gap exists between the cutout 322-2 (not visible but see the cutout 322-1 in FIG. 5B) and the ID of the first cylindrical portion 400 of the rubber boot 250. The leaked coolant accumulated in the bellowed portion 402 of the rubber boot 250 flows through the gap to the bottom of the processing chamber 100. The leaked coolant flows through the gap to the bottom of the processing chamber 100 without damaging components surrounding the coolant manifold 200 (e.g., the RF power supply located adjacent to the coolant manifold 200 as shown in FIG. 6A). One or more sensors at the bottom of the processing chamber 100 (shown in FIG. 6A) detect the leak.

FIGS. 6A and 6B schematically shows the arrangement of the coolant manifold 200 relative to the RF power supply 450 in the processing chamber 100. The components of the processing chamber 100 already described above are not described again for brevity. In FIG. 6A, the coolant manifold 200 is located adjacent to the RF power supply 450 at the bottom of the processing chamber 100. The RF power supply 450 supplies RF power to the stations 102 for generating plasma in the stations 102. As explained above, the rubber boots 250 mounted on the coolant manifold 200 prevent the coolant that may leak from the fittings and associated conduits from splashing on and damaging the RF power supply 450. Instead, the leaked coolant safely flows through the bottom of the rubber boots 250, through the gaps between the between the cutouts 322 and the ID of the first cylindrical portions 400 of the rubber boots 250, to the bottom of the processing chamber 100. One or more leak sensors 460 are located at the bottom of the processing chamber 100. The leak sensors 460 sense the leaked coolant. The controller 110 (shown in FIG. 1) receives data regarding the leaked coolant from the sensors 460 and provides alerts to an operator and/or performs other suitable mitigating operations including shutting off one or more valves associated with the conduits causing the leak.

In FIG. 6B, the RF power supply 450 comprises a low frequency (LF) power supply 452 and a high frequency (HF) power supply 454. The HF power supply 454 is stacked on top of the LF power supply 452. The enclosure of the HF power supply 454 can have a different size and shape than the enclosure of the LF power supply 452. The coolant flowing through the conduits 222 (shown in FIG. 2) to the pedestals 204 can also leak from the vicinity of the pedestals 204. The leaking coolant from the vicinity of the pedestals 204 can precipitate on the RF power supply 450 and damage the RF power supply 450. Specifically, the leaking coolant can precipitate on the HF power supply 454 and on the portions of the LF power supply 452 that are not covered by the HF power supply 454. As explained below with reference to FIGS. 7A-8C, the top covers of the enclosures of the HF and LF power supplies 454, 452 are typically not sealingly joined to the respective enclosures. As a result, gaps remain between the top covers and the enclosures. The leaking coolant can flow through the gaps and damage the HF and LF power supplies 454, 452.

FIGS. 7A-8C show shaped sealing assemblies that can close the gaps between the top covers and the enclosures of the HF and LF power supplies 454, 452 including those at the corners of the top covers and the enclosures of the HF and LF power supplies 454, 452. FIGS. 7A-7D show sealing assemblies for the HF power supply 454. FIGS. 8A-8C show sealing assemblies for the LF power supply 452. The following teachings regarding the various sealing assemblies apply equally to an RF power supply comprising a single enclosure and a single cover. The sealing assemblies described below can be used to close the gaps between the single cover and the single enclosure.

FIG. 7A shows a simplified example of an enclosure 500 and a top cover 502 of the HF power supply 454. For example, the enclosure 500 of the HF power supply 454 is octagonal in shape. Alternatively, the enclosure 500 of the HF power supply 454 can have any other shape. Regardless, the top cover 502 of the HF power supply 454 is typically not sealingly joined to the upper edges of the enclosure 500. As a result, gaps 504 exists between the outer edges of the top cover 502 and the upper inside edges of the enclosure 500 along the length of each side of the enclosure 500 and the top cover 502. The gaps 504 also exist between the outer edges of the top cover 502 and the upper inside edges of the enclosure 500 at the corners of the enclosure 500 and the top cover 502 as shown generally at 505.

FIGS. 7B-7D show various examples of sealing assemblies that seal the gaps 504. The sealing assemblies comprise a flexible taping material that is coated on one side with an adhesive material. The adhesive material can form a leakproof bond with a material of which the enclosure 500 and the top cover 502 are made (e.g., a metallic material). For example, FIG. 7B shows an example of a sealing assembly 510 that is specifically configured (shaped) to seal the gaps 504 at the corners 505. The sealing assembly 510 includes a first member 512, a second member 514, and a third member 516. The second member 514 folds from the first member 512 at 518. The third member 516 folds from the first member 512 at 520. The first, second, and third members 512, 514, 516 are integral and are not separate (disjoint) pieces. In other words, the sealing assembly 510 is a single piece.

The sealing assembly 510 is coated with the adhesive material on one side. The side of the first member 512 coated with the adhesive material is pressed on the top cover 502 at a corner 505 of the enclosure 500. The adhesive material of the first member 512 forms a leakproof bond with the top cover 502 at the corner 505. The second and third members 514, 516 are pressed against upper edge portions of the enclosure 500 on either side of the corner 505. The adhesive material of the second and third members 514, 516 forms a leakproof bond with the enclosure 500 at the corner 505. The sealing assembly 510 seals the gaps 504 at and around the corner 505 of the enclosure 500. A plurality of the sealing assembly 510 is used to seal the gaps 504 at and around the corners 505 of the enclosure 500.

FIG. 7C shows an example of a sealing assembly 530 used to seal the gaps 504 along the length of a side of the enclosure 500 and the top cover 502. The sealing assembly 530 includes a first member 532 and a second member 534. The second member 534 folds from the first member 532 at 536. The first and second members 532, 534 are integral and are not separate (disjoint) pieces. In other words, the sealing assembly 530 is a single piece.

The sealing assembly 530 is coated with the adhesive material on one side. The side of the first member 532 coated with the adhesive material is pressed on the top cover 502 along an edge of the top cover 502. The adhesive material of the first member 532 forms a leakproof bond with the top cover 502 along the edge of the top cover 502. The second member 534 is pressed against an upper edge portion of a side of the enclosure 500. The adhesive material of the second member 534 forms a leakproof bond with the enclosure 500 along the upper edge portion of the side of the enclosure 500. A plurality of the sealing assembly 530 is used to seal the gaps 504 between the edges of the top cover 502 and the upper edges of the enclosure 500.

FIG. 7D shows an example of the sealing assembly 530 with cutouts 538 and 540. The cutouts 538 and 540 can be specifically configured (shaped) to go around items (e.g., attachments) such as screwheads, portions of handles, connectors, etc. of the HF power supply 454 that may be mounted to the enclosure 500 and/or the top cover 502. While not shown, similar cutouts can also be provided in the sealing assembly 510. These cutouts ensure that the sealing assemblies 510, 530 form leakproof seals around the gaps 504 in the presence of these items that can otherwise (i.e., if the cutouts are not used) obstruct the sealing assemblies 510, 530 and that can otherwise (i.e., if the cutouts are not used) prevent the sealing assemblies 510, 530 from forming leakproof seals.

FIG. 8A shows a simplified example of an enclosure 600 and a top cover 602 of the LF power supply 452. For example, the enclosure 600 of the LF power supply 452 is rectangular in shape. Alternatively, the enclosure 600 of the LF power supply 452 can be of any other shape. Regardless, the footprint of the enclosure 600 of the LF power supply 452 may be larger than the footprint of the enclosure of the HF power supply 454 as shown in FIG. 6B. Accordingly, while the HF power supply 454 is stacked on top of the LF power supply 452, portions of the LF power supply 452 (e.g., corners in the example shown) may be exposed to any leaking coolant. Further, the top cover 602 of the LF power supply 452 is typically not sealingly joined to the upper edges of the enclosure 600. As a result, gaps 604 exists between the outer edges of the top cover 602 and the upper inside edges of the enclosure 600 along the length of each side of the enclosure 600 and the top cover 602. The gaps 604 also exist between the outer edges of the top cover 602 and the upper inside edges of the enclosure 600 at the corners of the enclosure 600 and the top cover 602 as shown generally at 605.

FIGS. 8B and 8C show examples of sealing assemblies that seal the gaps 604. The sealing assemblies comprise a flexible taping material that is coated on one side with an adhesive material. The adhesive material can form a leakproof bond with a material of which the enclosure 600 and the top cover 602 are made (e.g., a metallic material). For example, FIG. 8B shows an example of a sealing assembly 610 that is specifically configured (shaped) to seal the gaps 604 at the corners 605. The sealing assembly 610 includes a first member 612, a second member 614, and a third member 616. The second member 614 folds from the first member 612 at 618. The third member 616 folds from the first member 612 at 620. The first, second, and third members 612, 614, 616 are integral and are not separate (disjoint) pieces. In other words, the sealing assembly 610 is a single piece.

The sealing assembly 610 is coated with the adhesive material on one side. The side of the first member 612 coated with the adhesive material is pressed on the top cover 602 at a corner 605 of the enclosure 600. The adhesive material of the first member 612 forms a leakproof bond with the top cover 602 at the corner 605. The second and third members 614, 616 are pressed against upper edge portions of the enclosure 600 on either side of the corner 605. The adhesive material of the second and third members 614, 616 forms a leakproof bond with the enclosure 600. The sealing assembly 610 seals the gaps 604 at and around the corner 605 of the enclosure 600 at the corner. A plurality of the sealing assembly 610 is used to seal the gaps 604 at and around the corners 605 of the enclosure 600.

FIG. 8C shows an example of a sealing assembly 630 used to seal the gaps 604 along the length of a side of the enclosure 600 and the top cover 602. The sealing assembly 630 includes a first member 632 and a second member 634. The second member 634 folds from the first member 632 at 636. The first and second members 632, 634 are integral and are not separate (disjoint) pieces. In other words, the sealing assembly 630 is a single piece.

The sealing assembly 630 is coated with the adhesive material on one side. The side of the first member 632 coated with the adhesive material is pressed on the top cover 602 along an edge of the top cover 602. The adhesive material of the first member 632 forms a leakproof bond with the top cover 602 along the edge of the top cover 602. The second member 634 is pressed against an upper edge portion of a side of the enclosure 600. The adhesive material of the second member 634 forms a leakproof bond with the enclosure 600 along the upper edge portion of a side of the enclosure 600. A plurality of the sealing assembly 630 is used to seal the gaps 604 between the edges of the top cover 602 and the upper edges of the enclosure 600.

While not shown, the sealing assembly 630 can also include cutouts similar to those shown in FIG. 7D. The cutouts can be specifically configured (shaped) to go around items (e.g., attachments) such as screwheads, portions of handles, connectors, etc. of the LF power supply 452 that may be mounted to the enclosure 600 and the top cover 602. Further, while not shown, similar cutouts can also be provided in the sealing assembly 610. These cutouts ensure that the sealing assemblies 610, 630 form leakproof seals around the gaps 604 in the presence of these items that can otherwise (i.e., if the cutouts are not used) obstruct the sealing assemblies 610, 630 and that can otherwise (i.e., if the cutouts are not used) prevent the sealing assemblies 610, 630 from forming leakproof seals.

With the sealing assemblies 510, 530 installed on the HF power supply 454, if any of the coolant flowing through the conduits 222 (shown in FIG. 2) to the pedestals 204 leaks onto the HF power supply 454, the leaking coolant cannot flow through the gaps 504 into the HF power supply 454. Thus, the sealing assemblies 510, 530 protect the HF power supply 454 from any leaks in the conduits 222. Additionally, with the sealing assemblies 610, 630 installed on the LF power supply 452, if any of the coolant flowing through the conduits 222 (shown in FIG. 2) to the pedestals 204 leaks onto the LF power supply 452, the leaking coolant cannot flow through the gaps 604 into the LF power supply 452. Thus, the sealing assemblies 610, 630 protect the LF power supply 452 from any leaks in the conduits 222.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A device for supplying a coolant to a substrate processing chamber, the device comprising:
a block comprising a plurality of surfaces and a plurality of passages defined within the block;
an input port located on a first surface of the plurality of surfaces to receive the coolant;
a first set of ports located on a second surface of the plurality of surfaces to supply the coolant to a first component of the substrate processing chamber, the first set of ports in fluid communication with the input port via a first passage of the plurality of passages;
a second set of ports located on a third surface of the plurality of surfaces to receive the coolant from the first component; and
an output port located on a fourth surface of the plurality of surfaces to supply the coolant to a second component of the substrate processing chamber, the output port in fluid communication with the second set of ports via a second passage of the plurality of passages.

2. The device of claim 1 wherein the first and fourth surfaces are the same.

3. The device of claim 1 wherein the second and third surfaces are the same.

4. The device of claim 1 wherein each of the first and second sets of ports includes a plurality of ports.

5. The device of claim 1 wherein each of the first and second sets of ports includes a single port.

6. The device of claim 1 wherein the first and second passages are disjoint.

7. The device of claim 1 further comprising:
a first set of fittings extending from the first set of ports to connect the first set of ports to a first set of conduits, respectively, the first set of conduits supplying the coolant to the first component; and
a second set of fittings extending from the second set of ports to connect the second set of ports to a second set of conduits, respectively, the second set of conduits receiving the coolant from the first component.

8. The device of claim 7 wherein the first and second sets of fittings and the device are monolithic.

9. The device of claim 7 further comprising:
a first set of boots arranged coaxially around the first set of fittings and around portions of the first set of conduits extending from the first set of fittings; and
a second set of boots arranged coaxially around the second set of fittings and around portions of the second set of conduits extending from the second set of fittings.

10. The device of claim 9 wherein the first and second sets of boots are made of a flexible leakproof material.

11. The device of claim 9 wherein the first and second sets of boots are made of rubber.

12. The device of claim 9 wherein:
portions of the first and second sets of boots surround the first and second sets of fittings; and
the first and second sets of fittings are shaped differently than the portions of the first and second sets of boots to leave a gap between the first and second sets of fittings and the portions of the first and second sets of boots.

13. The device of claim 9 wherein the first and second sets of boots comprise:
first portions that surround the first and second sets of fittings;
second portions that extend from the first portions and that are bellowed; and
third portions that extend from the second portions and that surround portions of the first and second sets of conduits.

14. The device of claim 13 wherein the first and second sets of fittings are shaped differently than the first portions of the first and second sets of boots to leave a gap between the first and second sets of fittings and the first portions of the first and second sets of boots.

15. The device of claim 14 wherein in response the coolant leaking from at least one of the first and second sets of fittings, the leaked coolant accumulates in the second portion of at least one of the boots and flows through the gap.

16. The device of claim 14 wherein in response the coolant leaking from at least one of the portions of the first and second sets of conduits, the leaked coolant accumulates in the second portion of at least one of the boots and flows through the gap.

17. A substrate processing system comprising:
the device of claim 9; and
a radio frequency power supply to supply radio frequency power to the substrate processing chamber;
wherein the radio frequency power supply is located adjacent the device; and
wherein in response the coolant leaking from at least one of the first and second sets of fittings, at least one of the boots prevent the leaking coolant from the at least one of the first and second sets of fittings from flowing to the radio frequency power supply.

18. A substrate processing system comprising:
the device of claim 9; and
a radio frequency power supply to supply radio frequency power to the substrate processing chamber;
wherein the radio frequency power supply is located adjacent the device; and
wherein in response the coolant leaking from at least one of the portions of the first and second sets of conduits, at least one of the boots prevent the leaking coolant from the at least one of the portions of the first and second sets of conduits from flowing to the radio frequency power supply.

19. A substrate processing system comprising:
the device of claim 1;
the substrate processing chamber comprising:
a plurality of stations, the stations comprising respective pedestals to support a substrate and respective pedestal lift assemblies to move the pedestals; and
a spindle with a robot to transfer the substrate between the stations;
wherein the spindle is the first component; and
wherein the second component comprises at least one of the pedestal lift assemblies.

20. The system of claim 19 wherein:
the first and second sets of ports are connected to the spindle via respective conduits; and
the output port is connected to the at least one of the pedestal lift assemblies via one or more conduits.

21. The system of claim 19 wherein:
the first and second sets of ports are connected to the spindle via respective conduits; and
the output port is connected to two of the pedestal lift assemblies via a conduit that is bifurcated to the two of the pedestal lift assemblies.

22. The system of claim 19 further comprising a coolant source to supply the coolant to the input port via a first conduit and to receive the coolant from one of the pedestal lift assemblies via a second conduit.

23. The system of claim 19 further comprising a radio frequency power supply to supply radio frequency power to the stations, wherein the radio frequency power supply is located adjacent the device and at least partially under the at least one of the pedestal lift assemblies, the radio frequency power supply comprising:
an enclosure;
a cover attached to the enclosure; and
a plurality of sealing assemblies to seal gaps between the cover and the enclosure.

24. The system of claim 23 wherein the sealing assemblies are shaped to avoid attachments of the radio frequency power supply mounted to at least one of the enclosure and the cover of the radio frequency power supply.

25. The system of claim 23 wherein the sealing assemblies are configured to fold around edges and corners of the enclosure and the cover.

26. The system of claim 23 wherein the output port is connected to the at least one of the pedestal lift assemblies via one or more conduits, and wherein in response to the coolant leaking from the one or more conduits, the sealing assemblies prevent the leaking coolant from the one or more conduits from precipitating on the radio frequency power supply.

27. The system of claim 19 further comprising a radio frequency power supply to supply radio frequency power to the stations, wherein the radio frequency power supply is located adjacent the device, the radio frequency power supply comprising:
a first power supply comprising a first enclosure and a first cover attached to the first enclosure;
a second power supply comprising a second enclosure and a second cover attached to the second enclosure, the second power supply being of a smaller footprint than the first power supply and being stacked on the first power supply; and
a plurality of sealing assemblies to seal gaps between the first cover and the first enclosure and between the second cover and the second enclosure,
wherein the sealing assemblies are shaped to avoid attachments of the first and second power supplies, the attachments being mounted to at least one of the first enclosure and the first cover of the first power supply and to at least one of the second enclosure and the second cover of the second power supply.

28. The system of claim 27 wherein the output port is connected to the at least one of the pedestal lift assemblies via one or more conduits, and wherein in response to the coolant leaking from the one or more conduits, the sealing assemblies prevent the leaking coolant from the one or more conduits from precipitating on at least one of the first and second power supplies.

29. The system of claim 27 wherein the sealing assemblies are configured to fold around edges and corners of the first enclosure and the first cover and around edges and corners of the second enclosure and the second cover.
